(19) United States
(12) Patent Application Publication
(10) Pub. No.: US 2006/0130971 A1
(43) Pub. Date: Jun. 22, 2006

(54) Apparatus for generating plasma by RF power

(75) Inventors: Yu Chang, San Jose, CA (US); Gwo-Chuan Tzu, Sunnyvale, CA (US); Salvador P. Umotoy, Antioch, CA (US); Chien-Teh Kao, Sunnyvale, CA (US); William Kuang, Sunnyvale, CA (US); Xiaoxiong Yuan, San Jose, CA (US); Mei Chang, Saratoga, CA (US)

Correspondence Address: PATTERSON & SHERIDAN, LLP, 3040 POST OAK BOULEVARD, SUITE 1500, HOUSTON, TX, 77056, US

(73) Assignee: Applied Materials, Inc.

(21) Appl. No.: 11/137,200

(22) Filed: May 24, 2005

Related U.S. Application Data
(60) Provisional application No. 60/637,897, filed on Dec. 21, 2004.

(51) Int. Cl. C23F 1/00; H01L 21/306

(52) U.S. Cl. 156/345.48; 156/345.43

(57) ABSTRACT

A method and apparatus for processing a substrate is provided. In one aspect, the chamber comprises a chamber body and a support assembly at least partially disposed within the chamber body adapted to support a substrate thereon. The chamber further comprises a lid assembly disposed on an upper surface of the chamber body. The lid assembly includes a top plate and a gas delivery assembly which define a plasma cavity therebetween, wherein the gas delivery assembly is adapted to heat the substrate. A remote plasma source having a U-shaped plasma region is connected to the gas delivery assembly.

### CROSS-REFERENCE TO RELATED APPLICATIONS

This application claims benefit of U.S. provisional patent application Ser. No. 60/637,897, filed Dec. 21, 2004, which is herein incorporated by reference.

### BACKGROUND OF THE INVENTION

1. Field of the Invention

Embodiments of the present invention generally relate to semiconductor processing equipment. More particularly, embodiments of the present invention relate to generating plasma for a chemical vapor deposition (CVD) system or an in situ chamber cleaning system.

2. Description of the Related Art

A native oxide typically forms when a substrate surface is exposed to oxygen. Oxygen exposure occurs when the substrate is moved between processing chambers at atmospheric conditions, or when a small amount of oxygen remaining in a vacuum chamber contacts the substrate surface. Native oxides may also result when the substrate surface is contaminated by etching.

Oxygen exposure typically forms a thin native oxide film, such as between 5 and 20 angstroms, sufficient to cause difficulties in subsequent fabrication processes. Such difficulties usually affect the electrical properties of semiconductor devices formed on the substrate.

For example, a particular problem arises when native silicon oxide films are formed on exposed silicon containing layers, especially during processing of Metal Oxide Silicon Field Effect Transistor (“MOSFET”) structures. Silicon oxide films are electrically insulating and are undesirable at interfaces with contact electrodes or interconnecting electrical pathways because they cause high electrical contact resistance. In MOSFET structures, the electrodes and interconnecting pathways include silicide layers formed by depositing a refractory metal on bare silicon and annealing the layer to produce the metal silicide layer. Native silicon oxide films at the interface between the substrate and the metal reduce the compositional uniformity of the silicide layer by impeding the diffusion chemical reaction that forms the metal silicide. This results in lower substrate yields and increased failure rates due to overheating at the electrical contacts. The native silicon oxide film can also prevent adhesion of other CVD or sputtered layers which are subsequently deposited on the substrate.

Sputter etch processes have been tried to reduce contaminants in large features or in small features having aspect ratios smaller than about 4:1. However, sputter etch processes can damage delicate silicon layers by physical bombardment. In response, wet etch processes using hydrofluoric (HF) acid and deionized water, for example, have also been tried. Wet etch processes such as this, however, are disadvantageous in today's smaller devices where the aspect ratio exceeds 4:1, and especially where the aspect ratio exceeds 10:1. Particularly, the wet solution cannot penetrate into those sizes of vias, contacts, or other features formed within the substrate surface. As a result, the removal of the native oxide film is incomplete. Similarly, a wet etch solution, if successful in penetrating a feature of that size, is even more difficult to remove from the feature once etching is complete.

Another approach for eliminating native oxide films is a dry etch process, such as one utilizing fluorine-containing gases. One disadvantage to using fluorine-containing gases, however, is that fluorine is typically left behind on the substrate surface. Fluorine atoms or fluorine radicals left behind on the substrate surface detrimentally affect further processing of the substrate. For example, the fluorine atoms left behind continue to etch the substrate causing voids therein.

A more recent approach has been to form a fluorine/silicon-containing salt on the substrate surface that is subsequently removed by thermal anneal. In this approach, a thin layer of the salt is formed by reacting a fluorine-containing gas with the silicon oxide surface. The salt is then heated to an elevated temperature sufficient to dissociate the salt into volatile by-products which are then removed from the processing chamber. The formation of a reactive fluorine-containing gas is usually assisted by thermal addition or by plasma energy. The salt is usually formed at a reduced temperature that requires cooling of the substrate surface. This cooling then heating sequence is usually accomplished by transferring the substrate from a cooling chamber to a separate anneal chamber or furnace.

For various reasons, the fluorine processing sequence and wafer transfer to an anneal chamber is not desirable for cleaning small features. Namely, wafer throughput is greatly diminished because of the time involved to transfer the wafer. Also, the wafer is highly susceptible to further oxidation or other contamination during the transfer. Moreover, the cost of ownership is doubled because two separate chambers are needed to complete the process.

There is a need, therefore, for processing chambers capable of remote plasma generation, heating and cooling, and thereby capable of performing a single dry etch process in-situ.

### SUMMARY OF THE INVENTION

A processing chamber for processing a substrate is provided. In one aspect, the chamber comprises a chamber body and a support assembly at least partially disposed within the chamber body and adapted to support the substrate thereon. The chamber further comprises a lid assembly disposed on an upper surface of the chamber body. The lid assembly is in fluid communication with a remote plasma region having a U-shaped cross section for generating plasma. The remote plasma region is defined by a cylindrical electrode and a cup-shaped ground. An RF power source is connected to the cylindrical electrode.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a partial cross section view showing one embodiment of a processing chamber 100 having a remote plasma generator.

FIG. 2 is a cross section view of the remote plasma generator.

FIG. 3 is a schematic diagram of an exemplary multi-chamber processing system adapted to perform multiple processing operations.

FIGS. 4A-4H are sectional schematic views of an exemplary fabrication sequence for forming an exemplary active electronic device, such as a MOSFET structure, utilizing the dry etch process and chamber described herein.

### DETAILED DESCRIPTION

A processing chamber suitable for a variety of substrate processing methods is provided. An embodiment of the chamber is particularly useful for performing a plasma assisted dry etch process that requires both heating and cooling of the substrate surface without breaking vacuum. For example, the processing chamber described herein is envisioned to be best suited for a front-end-of line (FEOL) clean chamber for removing oxides and other contaminants from a substrate surface.

A “substrate surface”, as used herein, refers to any substrate surface upon which processing is performed. For example, a substrate surface may include silicon, silicon oxide, doped silicon, germanium, gallium arsenide, glass, sapphire, and any other materials such as metals, metal nitrides, metal alloys, and other conductive materials, depending on the application. A substrate surface may also include dielectric materials such as silicon dioxide, organosilicates, and carbon doped silicon oxides. The substrate itself is not limited to any particular size or shape. In one aspect, the term “substrate” refers to a round wafer having a 200 mm diameter or 300 mm diameter. In another aspect, the term “substrate” refers to any polygonal, square, rectangular, curved or otherwise non-circular workpiece, such as a substrate used in the fabrication of flat panel displays.

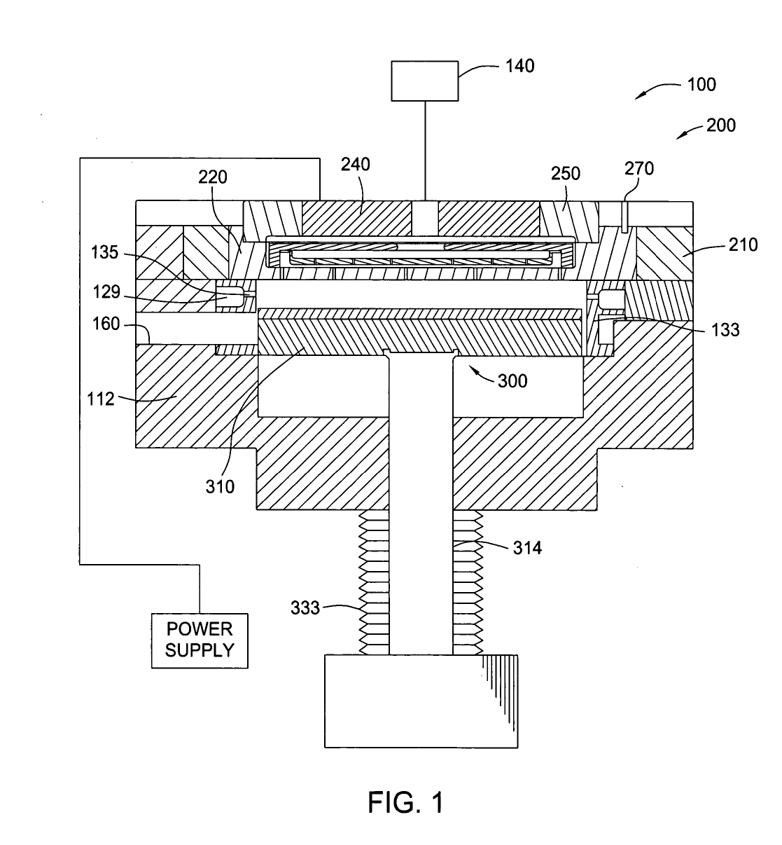

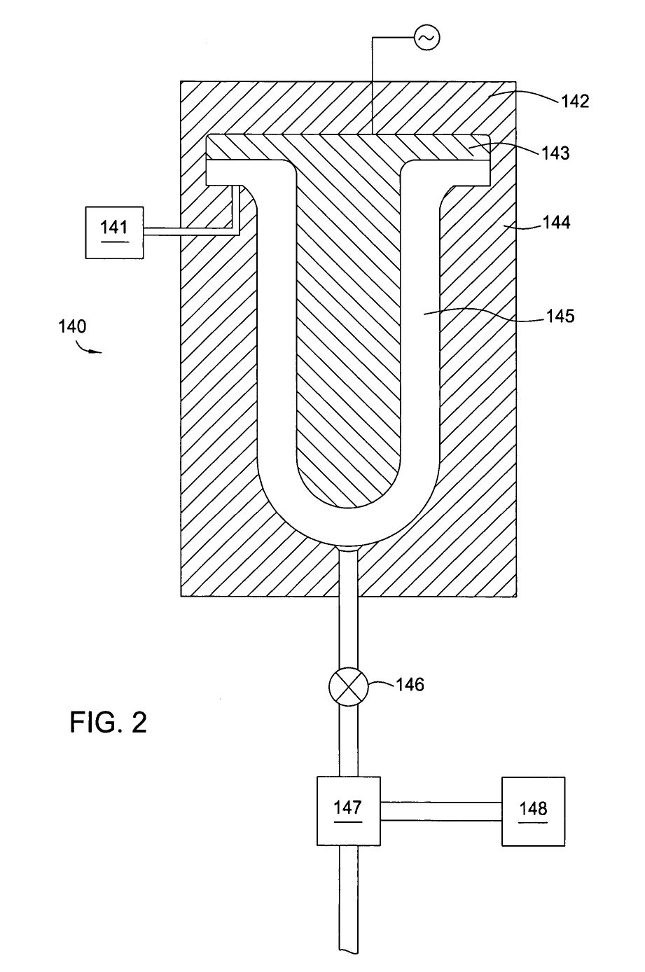

FIG. 1 is a partial cross sectional view showing one embodiment of a processing chamber 100. In this embodiment, the processing chamber 100 includes a lid assembly 200 disposed at an upper end of a chamber body 112, and a support assembly 300 at least partially disposed within the chamber body 112. The processing chamber also includes a remote plasma generator 140 having a remote electrode with a U-shaped cross section as described further by FIG. 2. The chamber 100 and the associated hardware are preferably formed from one or more process-compatible materials, for example, aluminum, anodized aluminum, nickel plated aluminum, nickel plated aluminum 6061-T6, stainless steel, as well as combinations and alloys thereof.

The support assembly 300 is partially disposed within the chamber body 112. The support assembly 300 is raised and lowered by the shaft (not shown) which is enclosed by bellows 333. The chamber body 112 includes a slit valve 160 formed in a sidewall thereof to provide access to the interior of the chamber 100. The slit valve 160 is selectively opened and closed to allow access to the interior of the chamber body 112 by a wafer handling robot (not shown). Wafer handling robots are well known to those with skill in the art, and any suitable robot may be used. In one embodiment, a wafer can be transported in and out of the process chamber 100 through the slit valve opening 160 to an adjacent transfer chamber and/or load-lock chamber (not shown), or another chamber within a cluster tool. Illustrative cluster tools include but are not limited to the PRODUCER™, CENTURA™, ENDURA™, and ENDURASL™ platforms available from Applied Materials, Inc. of Santa Clara, Calif.

The chamber body also includes a channel (not shown) formed therein for flowing a heat transfer fluid therethrough. The heat transfer fluid can be a heating fluid or a coolant and is used to control the temperature of the chamber body 112 during processing and substrate transfer. The temperature of the chamber body 112 is important to prevent unwanted condensation of the gas or byproducts on the chamber walls. Exemplary heat transfer fluids include water, ethylene glycol, or a mixture thereof. An exemplary heat transfer fluid may also include nitrogen gas.

The chamber body 112 further includes a liner 133 that surrounds the support assembly 300, and is removable for servicing and cleaning. The liner 133 is preferably made of a metal such as aluminum, or a ceramic material. However, any process compatible material may be used. The liner 133 may be bead blasted to increase the adhesion of any material deposited thereon, thereby preventing flaking of material which results in contamination of the chamber 100. The liner 133 typically includes one or more apertures 135 and a pumping channel 129 formed therein that is in fluid communication with a vacuum system. The apertures provide a flow path for gases into the pumping channel 129, and the pumping channel provides a flow path through the liner 133 so the gases can exit the chamber 100.

The vacuum system includes a vacuum pump (not shown) and a throttle valve (not shown) to regulate flow of gases within the chamber 100. The vacuum pump is coupled to a vacuum port (not shown) disposed on the chamber body 112, and is in fluid communication with the pumping channel 129 formed within the liner 133. The vacuum pump and the chamber body 112 are selectively isolated by the throttle valve 127 to regulate flow of the gases within the chamber 100. The terms “gas” and “gases” are used interchangeably, unless otherwise noted, and refer to one or more precursors, reactants, catalysts, carrier, purge, cleaning, combinations thereof, as well as any other fluid introduced into the chamber body 112.

The lid assembly 200 includes a number of components stacked on top of one another. For example, the lid assembly 200 includes a lid rim 210, gas delivery assembly 220, and a top plate 250. The lid rim 210 is designed to hold the weight of the components making up the lid assembly 200 and is coupled to an upper surface of the chamber body 112 via a hinge assembly (not shown in this view) to provide access to the internal chamber components. The gas delivery assembly 220 is coupled to an upper surface of the lid rim 210 and is arranged to make minimum thermal contact therewith. The components of the lid assembly 200 are preferably constructed of a material having a high thermal conductivity and low thermal resistance, such as an aluminum alloy with a highly finished surface, for example. Preferably, the thermal resistance of the components is less than about 5×10⁴ m² K/W.

Considering the gas delivery assembly 220 in more detail, the gas delivery assembly 220 includes a gas distribution plate or showerhead. A gas supply panel (not shown) is typically used to provide the one or more gases to the chamber 100. The particular gas or gases that are used depend upon the process to be performed within the chamber 100. For example, the typical gases include one or more precursors, reductants, catalysts, carriers, purge, cleaning, or any mixture or combination thereof. Typically, the one or more gases are introduced to the chamber 100 into the lid assembly 200 and then into the chamber body 112 through the gas delivery assembly 220. An electronically operated valve and/or flow control mechanism (not shown) may be used to control the flow of gas from the gas supply into the chamber 100.

In one aspect, the gas is delivered from a gas box (not shown) to the chamber 100 where the gas line tees into two separate gas lines which feed gases to the chamber body 112 as described above. Depending on the process, any number of gases can be delivered in this manner and can be mixed either in the chamber 100 or before they are delivered to the chamber 100.

Still referring to FIG. 1, the lid assembly may further include an electrode 240 to generate a plasma of reactive species within the lid assembly 200. In this embodiment, the electrode 240 is supported on the top plate 250 and is electrically isolated therefrom. An isolator filler ring (not shown) is disposed about a lower portion of the electrode 240 separating the electrode 240 from the top plate 250. An annular isolator (not shown) is disposed about an upper portion of the isolator filler ring and rests on an upper surface of the top plate 250, as shown in FIG. 1. An annular insulator (not shown) is then disposed about an upper portion of the electrode 240 so that the RF plate 240 is electrically isolated from the other components of the lid assembly 200. Each of these rings, the isolator filler and annular isolators can be made from aluminum oxide or any other insulative, process compatible material.

The electrode 240 is coupled to a power source (not shown) while the gas delivery assembly 220 is connected to ground. Accordingly, a plasma of the one or more process gases is struck in the volume formed between the electrode 240 and the gas delivery assembly 220. The plasma may also be contained within the volumes formed by blocker plates. In the absence of a blocker plate assembly, the plasma is struck and contained between the electrode 240 and the gas delivery assembly 220. In either embodiment, the plasma is well confined or contained within the lid assembly 200.

Any power source capable of activating the gases into reactive species and maintaining the plasma of reactive species may be used. For example, radio frequency (RF), direct current (DC), alternating current (AC), or microwave (MW) based power discharge techniques may be used. The activation may also be generated by a thermally based technique, a gas breakdown technique, a high intensity light source (e.g., UV energy), or exposure to an x-ray source. Alternatively, a remote activation source may be used, such as a remote plasma generator, to generate a plasma of reactive species which are then delivered into the chamber 100. Exemplary remote plasma generators are available from vendors such as MKS Instruments, Inc. and Advanced Energy Industries, Inc. Preferably, an RF power supply is coupled to the electrode 240.

The gas delivery assembly 220 may be heated depending on the process gases and operations to be performed within the chamber 100. In one embodiment, a heating element 270, such as a resistive heater for example, is coupled to the gas delivery assembly 220. In one embodiment, the heating element 270 is a tubular member and is pressed into an upper surface of the gas delivery assembly 220. The upper surface of the gas delivery assembly 220 includes a groove or recessed channel having a width slightly smaller than the outer diameter of the heating element 270, such that the heating element 270 is held within the groove using an interference fit.

The heating element 270 regulates the temperature of the gas delivery assembly 220 since the components of the delivery assembly 220, including the gas delivery assembly 220 and the blocker assembly 230 are each conductively coupled to one another. Additional details of the processing chamber may be found in U.S. patent application Ser. No. 11/063,645, filed Feb. 22, 2005 which is incorporated by reference herein.

FIG. 2 illustrates components of the remote plasma generator 140. Inlet 141 supplies gas to the generator 140. Insulators 142 insulate the electrode 143 from the ground 144. Chamber 145 provides a region for the plasma to ignite and flow toward valve 146. The valve is in fluid communication with a mixing region which is connected to an additional gas supply 148. The plasma and gases may flow from the valve 146 to the lid assembly 200. The U-shaped electrode 143 and chamber 145 have geometrical properties that may be defined by ratios. For example, the ratio of surface area of the electrode to the volume of the chamber is higher than traditional cylindrical, spherical, or rectangular electrodes that are housed in cylindrical or rectangular chambers with comparable dimensions such as height and width of the electrode and the chamber. Also, the ratio of the surface area of the electrode to the surface area of the walls of the chamber is higher for the U-shaped electrode than for traditional cylindrical, spherical, or rectangular electrodes that are housed in cylindrical or rectangular chambers with comparable dimensions such as height and width of the electrode and the chamber.

After extended periods of use or at designated times for scheduled maintenance, certain components of the chamber 100 described above are regularly inspected, replaced, or cleaned. These components are typically parts that are collectively known as the “process kit.” More particularly, components of the process kit include, but are not limited to the gas delivery assembly 220, the top plate (not shown), the edge ring (not shown), the liner 133, and the lift pins (not shown), for example. Any one or more of these components are typically removed from the chamber 100 and cleaned or replaced at regular intervals or according to an as-needed basis.

Furthermore, the processing chamber 100 may be integrated into a multi-processing platform, such as an Endura™ platform available from Applied Materials, Inc. located in Santa Clara, Calif. Such a processing platform is capable of performing several processing operations without breaking vacuum. Details of the Endura™ platform are described in commonly assigned U.S. Pat. Nos. 5,186,718 and 6,558,509 which are incorporated by reference herein.

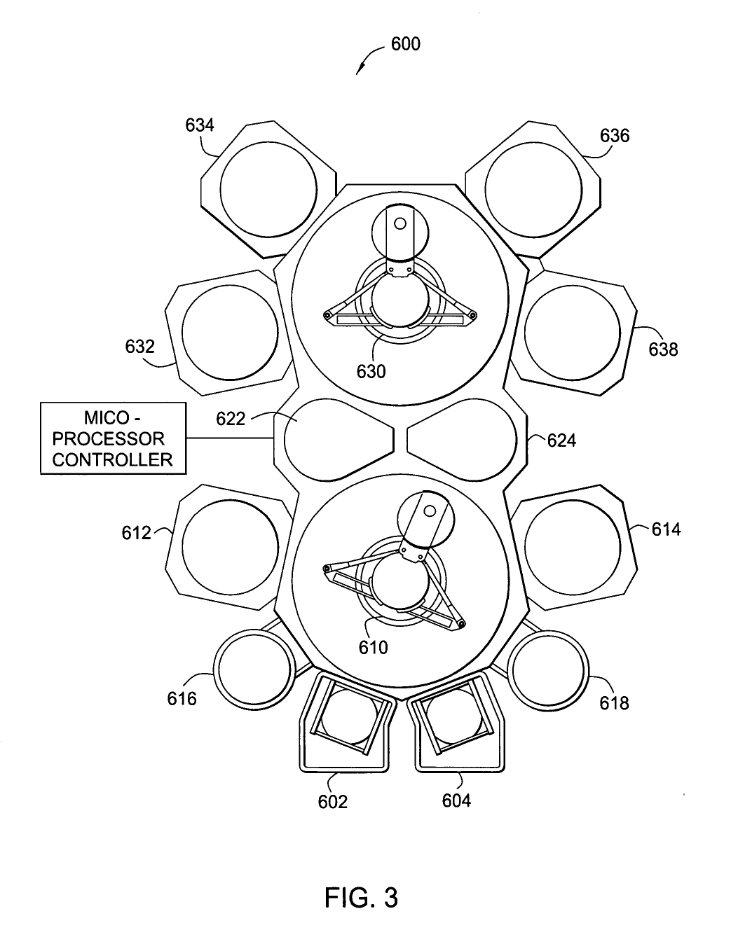

FIG. 3 is a schematic top-view diagram of such an exemplary multi-chamber processing system 600. The system 600 generally includes load lock chambers 602, 604 for the transfer of substrates into and out from the system 600. Typically, since the system 600 is under vacuum, the load lock chambers 602, 604 may “pump down” the substrates introduced into the system 600. A first robot 610 may transfer the substrates between the load lock chambers 602, 604, and a first set of one or more substrate processing chambers 612, 614, 616, 618 (four are shown). Each processing chamber 612, 614, 616, 618, can be outfitted to perform a number of substrate processing operations including the dry etch processes described herein in addition to cyclical layer deposition (CLD), atomic layer deposition (ALD), chemical vapor deposition (CVD), physical vapor deposition (PVD), etch, pre-clean, degas, orientation and other substrate processes.

The first robot 610 also transfers substrates to/from one or more transfer chambers 622, 624. The transfer chambers 622, 624 are used to maintain ultrahigh vacuum conditions while allowing substrates to be transferred within the system 600. A second robot 630 may transfer the substrates between the transfer chambers 622, 624 and a second set of one or more processing chambers 632, 634, 636, and 638. Similar to processing chambers 612, 614, 616, 618, the processing chambers 632, 634, 636, 638 can be outfitted to perform a variety of substrate processing operations including the dry etch processes described herein in addition to cyclical layer deposition (CLD), atomic layer deposition (ALD), chemical vapor deposition (CVD), physical vapor deposition (PVD), etch, pre-clean, degas, and orientation, for example. Any of the substrate processing chambers 612, 614, 616, 618, 632, 634, 636, 638 may be removed from the system 600 if not necessary for a particular process to be performed by the system 600. For example, integrating the etch step with other process steps can be crucial to reducing manufacturing time. Also, the remote plasma generator must have dimensions and process parameters that are compatible with the integrated tool. The compatibility must be precise not only to the integrated tool generally, but also to the process specific applications of the tool, much like plug and play compatibility in other industries.

For simplicity and ease of description, an exemplary dry etch process for removing silicon oxide using an ammonia (NH₃) and nitrogen trifluoride (NF₃) gas mixture performed within the chamber 100 will now be described. It is believed that the chamber 100 is advantageous for any dry etch process that benefits from a plasma treatment in addition to both substrate heating and cooling all within a single processing environment, including an anneal process.

Referring to FIG. 1, the dry etch process begins by placing a substrate (not shown), such as a semiconductor substrate for example, into the chamber 100. The substrate is typically placed into the chamber body 112 through the slit valve 160 and disposed on the upper surface of the support member 310. The substrate is chucked to the upper surface of the support member 310. Preferably, the substrate is chucked to the upper surface of the support member 310 by pulling a vacuum through the holes and grooves that are in fluid communication with a vacuum pump. The support member 310 is then lifted to a processing position within the chamber body 112, if not already in a processing position. The chamber body 112 is preferably maintained at a temperature of between about 50° C. and about 80° C., more preferably at about 65° C. This temperature of the chamber body 112 is maintained by passing a heat transfer medium through the walls of the chamber body 112.

The substrate is cooled below about 65° C., such as between about 15° C. and about 50° C., by passing a heat transfer medium or coolant through the fluid channel (not shown) formed within the support assembly 300. In one embodiment, the substrate is maintained below room temperature. In another embodiment, the substrate is maintained at a temperature of between about 22° C. and about 40° C. Typically, the support member 310 is maintained below about 22° C. to reach the desired substrate temperatures specified above. To cool the support member 310, a coolant is passed through a fluid channel in the support member 310. A continuous flow of coolant is preferred to better control the temperature of the support member 310. The coolant is preferably 50 percent by volume ethylene glycol and 50 percent by volume water. Of course, any ratio of water and ethylene glycol can be used so long as the desired temperature of the substrate is maintained.

The ammonia and nitrogen trifluoride gases are then introduced into the chamber 100 to form a cleaning gas mixture. The amount of each gas introduced into the chamber is variable and may be adjusted to accommodate, for example, the thickness of the oxide layer to be removed, the geometry of the substrate being cleaned, the volume capacity of the plasma, the volume capacity of the chamber body 112, as well as the capabilities of the vacuum system coupled to the chamber body 112. In one aspect, the gases are added to provide a gas mixture having at least about 1:1 molar ratio of ammonia to nitrogen trifluoride. In another aspect, the molar ratio of the gas mixture is at least about 3:1 (ammonia to nitrogen trifluoride). Preferably, the gases are introduced in the chamber 100 at a molar ratio of from about 5:1 (ammonia to nitrogen trifluoride) to about 30:1. More preferably, the molar ratio of the gas mixture is of from about 5:1 (ammonia to nitrogen trifluoride) to about 10:1. The molar ratio of the gas mixture may also fall between about 10:1 (ammonia to nitrogen trifluoride) and about 20:1.

A purge gas or carrier gas may also be added to the gas mixture. Any suitable purge/carrier gas may be used, such as argon, helium, hydrogen, nitrogen, or mixtures thereof, for example. Typically, the overall gas mixture is from about 0.05% to about 20% by volume of ammonia and nitrogen trifluoride. The remainder being the carrier gas. In one embodiment, the purge or carrier gas is first introduced into the chamber body 112 before the reactive gases to stabilize the pressure within the chamber body 112.

The operating pressure within the chamber body 112 can be variable. Typically, the pressure is maintained between about 100 mTorr and about 30 Torr. Preferably, the pressure is maintained between about 200 Torr and about 5 Torr.

An RF power of from about 5 to about 600 Watts is applied to the electrode 240 to ignite a plasma of the gas mixture within the volumes contained in the gas delivery assembly 220. Preferably, the RF power is less than about 100 Watts. More preferable is that the frequency at which the power is applied is very low, such as less than about 200 kHz.

The plasma energy dissociates the ammonia and nitrogen trifluoride gases into reactive species that combine to form a highly reactive ammonia fluoride (NH₄F) compound and/or ammonium hydrogen fluoride (NH₄F.HF) in the gas phase. These molecules then flow through the gas delivery assembly 220 via holes (not shown) to react with the substrate surface to be cleaned. In one embodiment, the carrier gas is first introduced into the chamber 100, a plasma of the carrier gas is generated, and then the reactive gases, ammonia and nitrogen trifluoride, are added to the plasma.

Not wishing to be bound by theory, it is believed that the etchant gas, NH₄F and/or NH₄F.HF, reacts with the silicon oxide surface to form ammonium hexafluorosilicate (NH₄)₂SiF₆, NH₃, and H₂O products. The NH₃, and H₂O are vapors at processing conditions and removed from the chamber 100 by the vacuum pump. In particular, the volatile gases flow through the apertures 135 formed in the liner 133 into the pumping channel 129 before the gases exit the chamber 100 through the vacuum port (not shown) into the vacuum pump. A thin film of (NH₄)₂SiF₆ is left behind on the substrate surface. This reaction mechanism can be summarized as follows:
NF₃+NH₃→NH₄F+NH₄F.HF+N₂
6NH₄F+SiO₂→(NH₄)₂SiF₆+H₂O
(NH₄)₂SiF₆+heat→NH₃+HF+SiF₄

After the thin film is formed on the substrate surface, the support member 310 having the substrate supported thereon is elevated to an anneal position in close proximity to the heated gas delivery assembly 220. The heat radiated from the gas delivery assembly 220 should be sufficient to dissociate or sublimate the thin film of (NH₄)₂SiF₆ into volatile SiF₄, NH₃, and HF products. These volatile products are then removed from the chamber 100 by the vacuum pump as described above.

The thermal energy to dissociate the thin film of (NH₄)₂SiF₆ into its volatile components is convected or radiated by the gas delivery assembly 220. The distance between the upper surface of the substrate having the thin film thereon and the gas delivery assembly 220 is not critical and is a matter of routine experimentation. A person of ordinary skill in the art can easily determine the spacing required to efficiently and effectively vaporize the thin film without damaging the underlying substrate. It is believed, however, that a spacing of between about 0.254 mm (10 mils) and about 5.08 mm (200 mils) is effective.

Once the film has been removed from the substrate, the chamber is purged and evacuated. The cleaned substrate is then removed from the chamber by lowering the substrate to the transfer position, de-chucking the substrate, and transferring the substrate through the slit valve 160.

A controller (not shown) regulates the operations of the chamber. The system controller operates under the control of a computer program stored on a hard disk drive of a computer. The computer program dictates the process sequencing and timing, mixture of gases, chamber pressures, RF power levels, susceptor positioning, slit valve opening and closing, wafer cooling and other parameters of a particular process. The interface between a user and the system controller is preferably via a CRT monitor and light pen (not shown). In a preferred embodiment two monitors are used, one monitor mounted in the clean room wall for the operators and the other monitor behind the wall for the service technicians.

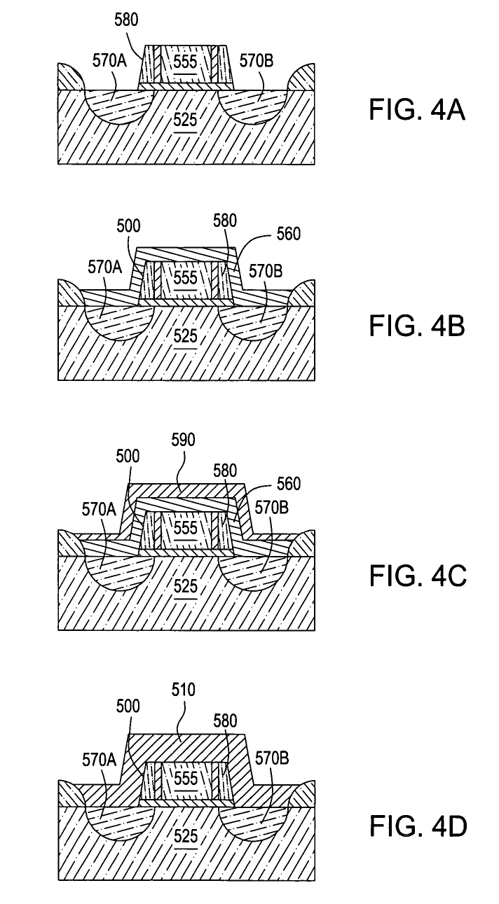

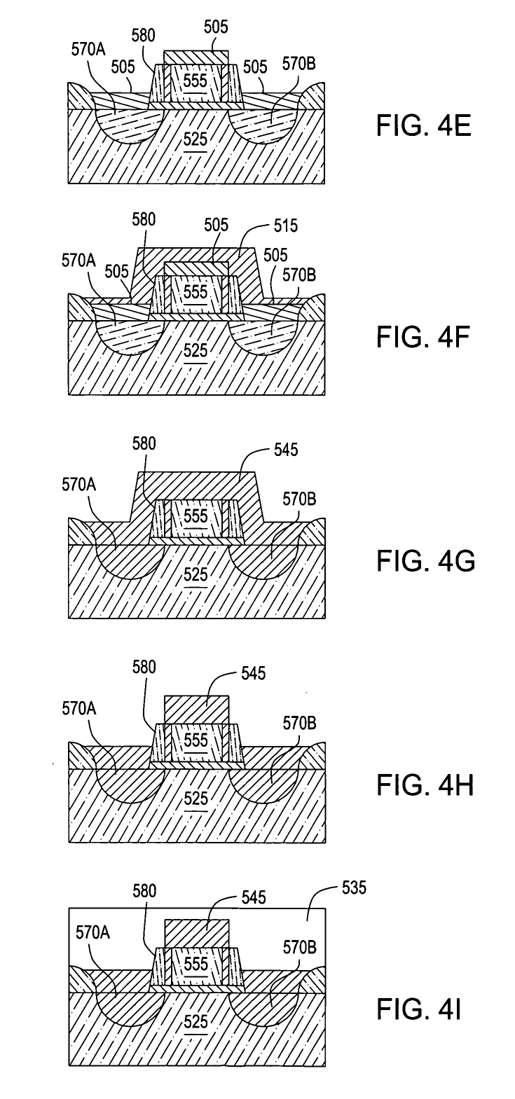

FIGS. 4A-4I are sectional schematic views of an exemplary fabrication sequence for forming an exemplary active electronic device, such as a MOSFET structure, utilizing the dry etch process and the chamber described herein. Referring to FIGS. 4A-4I, the exemplary MOSFET structure may be formed on a semiconductor material, for example a silicon or gallium arsenide substrate 525. Preferably, the substrate 525 is a silicon wafer having a <100> crystallographic orientation and a diameter of 150 mm (6 inches), 200 mm (8 inches), or 300 mm (12 inches). Typically, the MOSFET structure includes a combination of (i) dielectric layers, such as silicon dioxide, organosilicate, carbon doped silicon oxide, phosphosilicate glass (PSG), borophosphosilicate glass (BPSG), silicon nitride, or combinations thereof; (ii) semiconducting layers such as doped polysilicon, and n-type or p-type doped monocrystalline silicon; and (iii) electrical contacts and interconnect lines formed from layers of metal or metal silicide, such as tungsten, tungsten silicide, titanium, titanium silicide, cobalt silicide, nickel silicide, or combinations thereof.

Referring to FIG. 4A, fabrication of the active electronic device begins by forming electrical isolation structures that electrically isolate the active electronic device from other devices. There are several types of electrical isolation structures as generally described in VLSI Technology, Second Edition, Chapter 11, by S. M. Sze, McGraw-Hill Publishing Company (1988), which is incorporated herein by reference. In one version, a field oxide layer (not shown) having a thickness of about 2,000 angstroms is first grown over the entire substrate 525, and portions of the oxide layer are removed to form field oxide barriers which surround exposed regions in which the electrically active elements of the device are formed. The exposed regions are thermally oxidized to form a thin gate oxide layer having a thickness of from about 50 to about 300 angstroms. A polysilicon layer is then deposited on the substrate 525, patterned, and etched to create a gate electrode 555. The surface of the polysilicon gate electrode 555 is reoxidized to form an insulating dielectric layer 560.

Referring to FIG. 4B, the source and drain 570A,B are next formed by doping the appropriate regions with suitable dopant atoms. For example, on p-type substrates 525, an n-type dopant species comprising arsenic or phosphorous is used. After the implantation process, the dopant is driven into the substrate 525 by heating the substrate, for example, in a rapid thermal processing (RTP) apparatus. Thereafter, the oxide layer covering the source and drain regions 570A,B is stripped in a conventional stripping process to remove any impurities caused by the implantation process which are trapped in the oxide layer.

Referring to FIGS. 4A, a silicon nitride layer is deposited on the gate electrode 555 and the surrounding substrate 525 by low-pressure chemical vapor deposition (LPCVD) using a gas mixture of SiH₂, Cl₂, and NH₃. The silicon nitride layer is then etched using reactive ion etching (RIE) techniques to form nitride spacers 580 on the sidewall of the gate electrode 555, as shown in FIG. 4A. The spacers 580 electrically isolate the silicide layer formed on the top surface of the gate 555 from other silicide layers deposited over the source 570A and drain 570B. It should be noted that the electrical isolation sidewall spacers 580 and overlayers can be fabricated from other materials, such as silicon oxide. The silicon oxide layers used to form sidewall spacers 580 are typically deposited by CVD or PECVD from a feed gas of tetraethoxysilane (TEOS) at a temperature in the range of from about 600° C. to about 1,000° C.

Referring to FIG. 4A, a native silicon oxide layer forms on exposed silicon surfaces by exposure to the atmosphere before and after the processes. The native silicon oxide layer must be removed prior to forming conductive metal silicide contacts on the gate 555, source 570A, and drain 570B to improve the alloying reaction and electrical conductivity of the metal suicide formed. The native silicon oxide layer can increase the electrical resistance of the semiconducting material, and adversely affect the silicidation reaction of the silicon and metal layers that are subsequently deposited on the substrate 525. Therefore, it is necessary to remove this native silicon dioxide layer using the dry etch process described herein prior to forming metal silicide contacts or conductors for interconnecting active electronic devices on the substrate 525. The dry etch process removes the native silicon oxide layers to expose the source 570A, drain 570B, and the top surface of the gate electrode 555 as shown in FIG. 4A.

Thereafter, as illustrated in FIG. 4B, a PVD sputtering process is used to deposit a layer of metal 500 over the entire substrate 525. Conventional furnace annealing is then used to anneal the metal and silicon layers to form metal silicide in regions in which the metal layer 500 is in contact with silicon. Annealing is typically performed in a separate processing system. Accordingly, FIG. 4C illustrates a protective cap layer 590 may be deposited over the metal 500. The cap layers are typically nitride materials and may include one or more materials selected from the group consisting of titanium nitride, tungsten nitride, tantalum nitride, nafnium nitride, and silicon nitride. The cap layer 590 may be deposited by any deposition process, preferably by PVD.

FIG. 4D illustrates the results of annealing by heating the substrate 525 to a temperature of between about 600° C. and about 800° C. in an atmosphere of nitrogen for about 30 minutes. Alternatively, the metal silicide 510 can be formed utilizing a rapid thermal annealing process in which the substrate 525 is rapidly heated to about 1000° C. for about 30 seconds. Suitable conductive metals include cobalt, titanium, nickel, tungsten, platinum, and any other metal that has a low contact resistance and that can form a reliable metal silicide contact on both polysilicon and monocrystalline silicon.

Unreacted portions of the metal layer 500 can be removed by a wet etch using aqua regia, (HCl and HNO₃) which removes the metal without attacking the metal silicide 505; the spacer 580, or the field oxide 545A,B, thus leaving a self-aligned metal silicide contact on the gate 555, source 570A, and drain 570B, as shown in FIG. 4E. Thereafter, FIG. 4F illustrates an insulating cover layer 515 comprising, for example, silicon oxide, BPSG, or PSG, can be deposited on the electrode structures. The insulating cover layer is deposited by means of chemical-vapor deposition in a CVD chamber, in which the material condenses from a feed gas at low or atmospheric pressure, as for example, described in commonly assigned U.S. Pat. No. 5,500,249, issued Mar. 19, 1996, which is incorporated herein by reference. Thereafter, the substrate 525 is annealed at glass transition temperatures to form a smooth planarized surface on the substrate 525, as illustrated by FIG. 4G.

Unreacted portions of metal can be removed by a wet etch using aqua regia, (HCl and HNO₃) which removes the metal without attacking the metal silicide 545; the spacer 580, or the field oxide 545A,B, thus leaving a self-aligned metal silicide contact on the gate 555, source 570A, and drain 570B, as shown in FIG. 4H. Next, bulk metal is deposited as shown as bulk fill 535. The bulk metal may be tungsten or some other metal.

Referring to FIG. 3, a particular embodiment of the multi-processing system 600 to form the MOSFET structure described above includes two dry etch chambers 100 as described above, two physical vapor deposition chambers to deposit the metal 500 and two physical vapor deposition chambers to deposit the optional cap layer (not shown). Any one of the processing chambers 612, 614, 616, 618, 632, 634, 636, 638 shown in FIG. 3 represent the PVD chambers and dry etch chambers.

Although the process sequence above has been described in relation to the formation of a MOSFET device, the dry etch process described herein can also be used to form other semiconductor structures and devices that have other metal silicide layers, for example, suicides of tungsten, tantalum, molybdenum. The cleaning process can also be used prior to the deposition of layers of different metals including, for example, aluminum, copper, cobalt, nickel, silicon, titanium, palladium, hafnium, boron, tungsten, tantalum, or mixtures thereof.

Unless otherwise indicated, all numbers expressing quantities of ingredients, properties, reaction conditions, and so forth, used in the specification and claims are to be understood as approximations. These approximations are based on the desired properties sought to be obtained by the present invention, and the error of measurement, and should at least be construed in light of the number of reported significant digits and by applying ordinary rounding techniques. Further, any of the quantities expressed herein, including temperature, pressure, spacing, molar ratios, flow rates, and so on, can be further optimized to achieve the desired etch selectivity and particle performance.

While the foregoing is directed to embodiments of the present invention, other and further embodiments of the invention may be devised without departing from the basic scope thereof, and the scope thereof is determined by the claims that follow.

1. A processing chamber for a substrate, comprising:
a chamber body defining a processing region;
a support assembly at least partially disposed within the chamber body and adapted to support a substrate within the processing region; and
a plasma source having a cylindrical electrode and a ground electrode defining a plasma region in communication with the processing region.

2. The chamber of claim 1, wherein the ground electrode is a cup-shaped electrode spaced apart from the cylindrical electrode.

3. The chamber of claim 1, wherein the cylindrical electrode is coupled to a radio frequency source, microwave source, or a source of direct current or alternating current.

4. The chamber of claim 3, wherein the cylindrical electrode is coupled to a radio frequency source.

5. The chamber of claim 4, wherein the ground electrode has greater surface area than the cylindrical electrode.

6. The chamber of claim 1, wherein the ground electrode is below the cylindrical electrode.

7. The chamber of claim 1, further comprising one or more fluid channels for flowing heat transfer medium through the support assembly.

8. A processing chamber for a substrate, comprising:
a chamber body defining a processing region;
a support assembly at least partially disposed within the chamber body and adapted to support a substrate within the processing region; and
a remote plasma source having a cylindrical electrode and a ground electrode defining a remote plasma region in communication with the processing region.

9. The chamber of claim 8, further comprising one or more fluid channels for flowing a heat transfer medium through the support assembly.

10. The chamber of claim 8, wherein the ground electrode is a cup-shaped electrode spaced apart from the cylindrical electrode.

11. The chamber of claim 8, wherein the cylindrical electrode is coupled to a radio frequency source, microwave source, or a source of direct current or alternating current.

12. The chamber of claim 11, wherein the cylindrical electrode is coupled to a radio frequency source.

13. The chamber of claim 12, wherein the ground electrode has greater surface area than the cylindrical electrode.

14. The chamber of claim 8, wherein the ground electrode is below the cylindrical electrode.

15. A processing chamber for a substrate, comprising:
a chamber body defining a processing region;
a support assembly at least partially disposed within the chamber body and adapted to support a substrate within the processing region; and
a cylindrical electrode and a cup-shaped electrode defining a plasma region in communication with the processing region.

16. The chamber of claim 15, further comprising one or more fluid channels for flowing a heat transfer medium through the support assembly.

17. The chamber of claim 15, wherein the plasma source is a remote plasma source.

18. The chamber of claim 15, wherein the cylindrical electrode is coupled to a radio frequency source, microwave source, or a source of direct current or alternating current.

19. The chamber of claim 15, wherein the cup-shaped electrode has greater surface area than the cylindrical electrode.

20. The chamber of claim 15, wherein the cup-shaped electrode is below the cylindrical electrode.
